(19) United States
(12) Patent Application Publication
(10) Pub. No.: US 2024/0203842 A1
(43) Pub. Date: Jun. 20, 2024

(54) SEMICONDUCTOR DEVICE ASSEMBLY WITH A CIRCULAR SEGMENTED PACKAGE EDGE

(71) Applicant: Micron Technology, Inc., Boise, ID (US)

(72) Inventors: Seng Kim YE, Singapore (SG); Kelvin Aik Boo TAN, Singapore (SG); Hong Wan NG, Singapore (SG); Chin Hui CHONG, Singapore (SG); Ling PAN, Singapore (SG); See Hiong LEOW, Singapore (SG)

(21) Appl. No.: 18/530,905

(22) Filed: Dec. 6, 2023

Related U.S. Application Data
(60) Provisional application No. 63/387,432, filed on Dec. 14, 2022.

(51) Int. Cl. H01L 23/495; H01L 21/56; H01L 23/31; H01L 25/065

(52) U.S. Cl. CPC H01L 23/49565; H01L 21/56; H01L 23/3114; H01L 25/0657

(57) ABSTRACT

Implementations described herein relate to various semiconductor device assemblies. In some implementations, a semiconductor device assembly includes a circuit substrate comprising a first substrate surface, a second substrate surface arranged opposite to the first substrate surface, and a substrate edge that extends from the first substrate surface to the second substrate surface; a series of holes arranged along the substrate edge of the circuit substrate, wherein each hole of the series of holes extends at least partially from the first substrate surface toward the second substrate surface; at least one die arranged on the first substrate surface; and a package casing disposed over the first substrate surface, wherein the package casing encapsulates the at least one die and the first substrate surface, and wherein the package casing fills each hole of the series of holes.

### CROSS REFERENCE TO RELATED APPLICATION

This Patent application claims priority to U.S. Provisional Patent Application No. 63/387,432, filed on Dec. 14, 2022, and entitled “SEMICONDUCTOR DEVICE ASSEMBLY WITH A CIRCULAR SEGMENTED PACKAGE EDGE.” The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a semiconductor device assembly with a circular segmented package edge.

### BACKGROUND

A semiconductor package includes a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components are interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes means for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3A illustrates an example circuit substrate assembly strip according to one or more implementations.

FIG. 3B illustrates a top view diagram and a perspective view diagram of an example substrate edge along which a series of holes is formed according to one or more implementations.

FIG. 4 illustrates a front view of an example semiconductor device assembly that may be manufactured using techniques described herein according to one or more implementations.

FIG. 5A illustrates a front view of an example semiconductor device assembly that may be manufactured using techniques described herein according to one or more implementations.

FIG. 5B illustrates a top view of the semiconductor device assembly illustrated in FIG. 5A according to one or more implementations.

FIG. 5C illustrates a side view of the semiconductor device assembly illustrated in FIG. 5A according to one or more implementations.

FIGS. 6A-6G illustrate a process flow of an example method of forming one or more semiconductor device assemblies.

FIG. 7 is a flowchart of an example method of forming an integrated assembly or memory device having a semiconductor package assembly with a circular segmented package edge.

FIG. 8 is a flowchart of an example method of forming an integrated assembly or memory device having a semiconductor package assembly with a circular segmented package edge.

### DETAILED DESCRIPTION

A semiconductor package assembly may be one type of semiconductor device assembly that is structured to house one or more dies. During manufacturing, one or more dies are mounted to a device region of a circuit substrate (e.g., an assembly strip) and a package casing material (e.g., mold compound) is formed over the device region to encapsulate the one or more dies. A singulation is performed, for example, by sawing through the package casing material and the circuit substrate along saw paths, to separate the device region from a remaining portion of the circuit substrate and to form the semiconductor package assembly whose package edges are defined by the saw paths along which the sawing was performed. Accordingly, the package edges define an outer perimeter of the semiconductor package assembly.

In some cases, a die edge of a die may be located in close proximity to a saw path (e.g., a package edge). This situation is becoming more common as sizes of semiconductor device assemblies become smaller and more compact. As semiconductor device assemblies shrink in size, the saw paths used to make the package edges move closer to die edges of the dies covered by the package casing material. Vibration is produced during the singulation due the sawing performed along the saw paths. Cracking at the circuit substrate may occur during sawing as a result of mechanical stress created by the vibration, particularly at the die edge, where the circuit substrate is most vulnerable to the vibration. Accordingly, substrate cracks (e.g., cracked lines) may form during the singulation. A substrate crack may cause a delamination between the package casing material and the circuit substrate to occur at the substrate crack, resulting in a possible failure of the semiconductor package assembly.

The mechanical stress applied to the circuit substrate at the die edge during the singulation (e.g., due to vibration) increases as a distance between the die edge and the saw path decreases. For example, a die-edge-to-package-edge distance of less than 100 micrometers (μm) is becoming more common. The circuit substrate at the die edge is increasingly more vulnerable to cracking at die-edge-to-package-edge distances of less than 100 μm. Thus, as semiconductor device assemblies shrink in size, substrate cracks formed at the die edge are becoming more prevalent.

In some implementations, a weakest zone of a circuit substrate is shifted from a die edge to a saw path (e.g., to a package edge). As a result, occurrence of substrate cracks formed during singulation can be reduced, or prevented entirely.

For example, in some implementations, a series of holes is formed in the circuit substrate along one or more saw paths to shift the weakest zone of a circuit substrate from the die edge to the saw path at which the series of holes are formed (e.g., to a package edge). The series of holes are configured to case the singulation process, preventing cracking from occurring in the circuit substrate at the die edge. For example, by forming the series of holes along a die path, vibration that would have been transferred to the die edge during singulation can be reduced. As a result, substrate cracks at the die edge can be prevented, even as a distance between the die edge and the saw path decreases.

During the singulation process, a cut is made along the saw path through the series of holes, leaving part of each hole (e.g., as a circular segment) as part of the substrate edge of the circuit substrate. This substrate edge is coincident with the package edge of the semiconductor package assembly. Additionally, a package casing material is used to fill the series of holes during an encapsulation process (e.g., prior to singulation). In this way, the package casing material is mechanically (e.g., structurally) interlocked with the circuit substrate at the substrate edge/package edge. As a result, filled holes remain at the substrate edge after singulation, which may provide additional mechanical strength to the substrate edge.

In some implementations, the series of holes are blind holes that extend partially through the circuit substrate. In some implementations, the series of holes are through-holes that extend entirely through the circuit substrate. In either case, the package casing material can be used to fill the series of holes, improving the mechanical strength of the circuit substrate at the substrate edge.

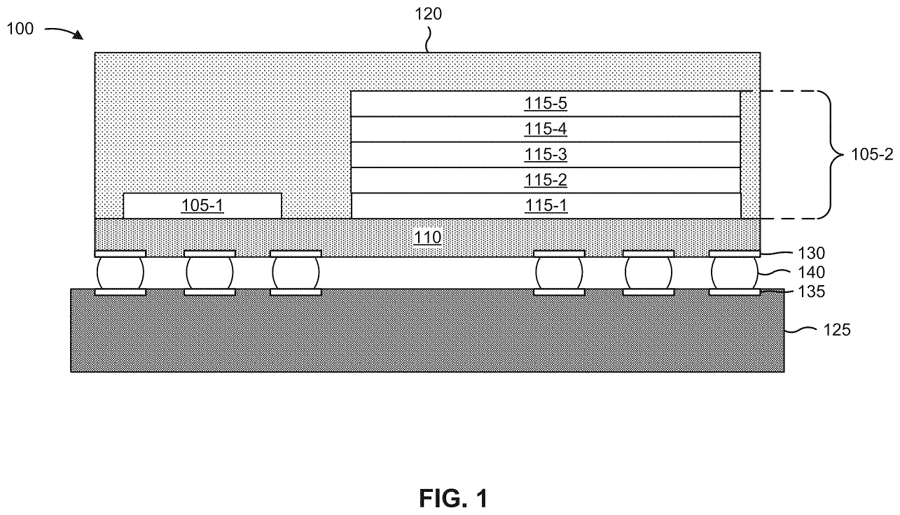

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As indicated above, FIG. 1 is provided as an example. Other examples may differ from what is described with regard to FIG. 1.

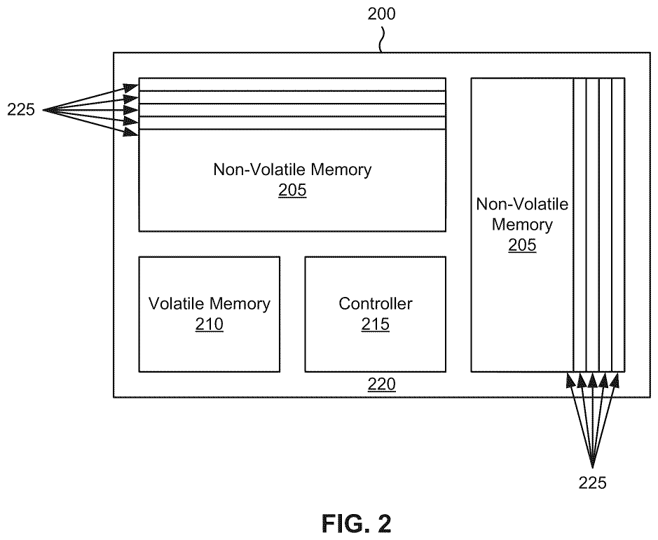

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes stacked semiconductor dies 225, as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

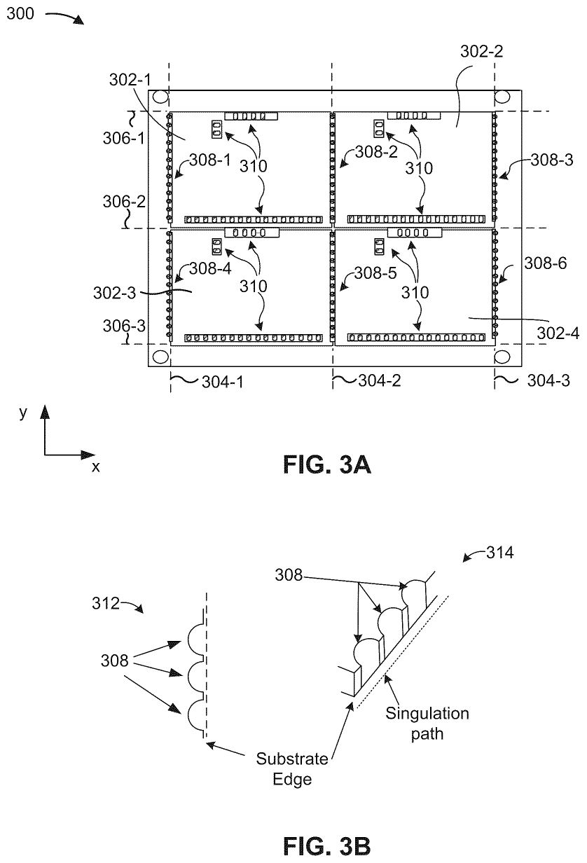

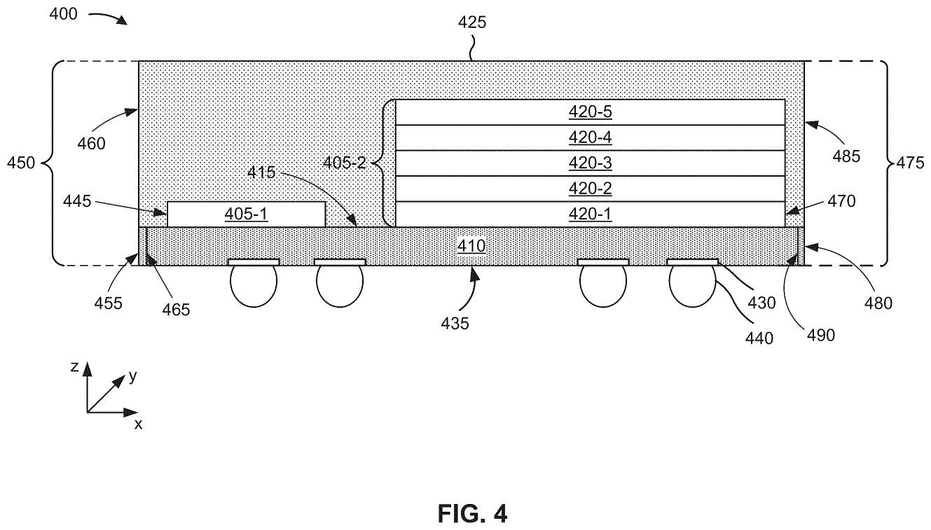

FIG. 3A illustrates an example circuit substrate assembly strip 300 according to one or more implementations. The circuit substrate assembly strip 300 may be a printed circuit board (PCB) assembly strip or another type of circuit substrate on which various device components are mounted. The circuit substrate assembly strip 300 includes multiple device regions 302, shown as four device regions 302-1 through 302-4. Each device region 302 is configured to become a part of a separate semiconductor device assembly after a singulation process. Accordingly, each device region 302 is configured to have a corresponding set of device components mounted thereto that will be covered by a casing material and eventually singulated as part of a separate semiconductor device assembly. The corresponding set of device components may include, for example, one or more integrated circuits (e.g., one or more dies), one or more controllers (e.g., a microcontroller, a memory controller, etc.), and one or more passive components, such as capacitors or resistors.

According to the present example, four semiconductor device assemblies can be produced from the four device regions 302-1 through 302-4 based on a one-to-one correspondence. However, it will be appreciated that a number of device regions may be less than or greater than four. Each semiconductor device assembly is an example of the apparatus 100 described above in connection with FIG. 1. In some implementations, each semiconductor device assembly may be a memory device similar to the memory device 200 described in connection with FIG. 2.

Each device region 302 is delineated by a plurality of first singulation paths 304, shown as first singulation paths 304-1 through 304-3, and a plurality of second singulation paths 306, shown as second singulation paths 306-1 through 306-3. The first singulation paths 304 extend parallel to a y-axis and the second singulation paths 306 extend parallel to an x-axis. In some implementations, the first singulation paths 304 and the second singulation paths 306 are saw paths along which the device regions 302 are singulated (e.g., separated) by sawing. After singulation, each device region 302 is defined by substrate edges that are formed by singulation (e.g., sawing) along the first singulation paths 304 and the second singulation paths 306. These substrate edges may be part of corresponding package edges of the semiconductor device assembly. In other words, each substrate edge may be coincident with a package edge of a corresponding semiconductor device assembly.

In addition, a series of holes 308 may be formed along some or along all of the first singulation paths 304 and the second singulation paths 306. In some implementations, the series of holes 308 are through-holes that extend entirely through the circuit substrate assembly strip 300. In some implementations, the series of holes 308 are blind holes that extend only partially through the circuit substrate assembly strip 300.

Multiple series of holes 308 are shown as series of holes 308-1 through 308-6 that are formed along the substrate edges of the device regions 302. In the present example, the series of holes 308 are formed along the first singulation paths 304. Thus, the device regions 302 are delimitated by the series of holes 308 along their substrate edges that extend parallel to the y-axis. In other words, the substrate edges that extend parallel to the y-axis are perforated edges that are formed by the series of holes 308. The substrate edges that extend parallel to the y-axis, which also correspond to package edges that extend parallel to the y-axis, may each be in close proximity (e.g., less than 100 μm) to a die edge of a die mounted to a device region 302 of the circuit substrate assembly strip 300.

As a result of the series of holes 308 formed along the first singulation paths 304, a weak zone of the circuit substrate assembly strip 300 is shifted away from the die edge to the substrate edges defined by the first singulation paths 304 that include the series of holes 308. During the singulation, a cut is performed through the series of holes 308, cutting the series of holes 308 substantially in half along the first singulation paths 304. Thus, adjacent device regions 302, when separated, will each include a portion of the series of holes 308 that were previously shared along a boundary line (e.g., along a singulation path).

For example, the device region 302-1 includes a first remaining portion of the series of holes 308-2 and the device region 302-2 includes a second remaining portion of the series of holes 308-2. The first remaining portion of the series of holes 308-2 has a first shape that may be defined by a first circular segment and the second remaining portion of the series of holes 308-2 has a second shape that may be defined by a second circular segment. As defined herein, a circular segment is a shape defined by an arc and a chord of a circle. In other words, the circular segment has a perimeter bounded by the arc and the chord of the circle. A semicircle is one example of a circular segment. In some implementations, the first remaining portion and the second remaining portion may be referred to as half-holes. In some implementations, the first remaining portion and the second remaining portion may be referred to as castellation holes. In some implementations, a substrate edge that includes a remaining portion of one of the series of holes 308 may be referred to as a circular segmented edge, with each hole of the series of holes 308 defining a respective concaved segment of the substrate edge.

The first shape defined by the first circular segment and the second shape defined by the first circular segment may both be substantially semicircular, or the first shape defined by the first circular segment may be equal to or larger than a semicircle and the second shape defined by the second circular segment may be smaller than a semicircle, or the first shape defined by the first circular segment may be smaller than a semicircle and the second shape defined by the second circular segment may be equal to or larger than a semicircle, or the first shape defined by the first circular segment may be smaller than a semicircle and the second shape defined by the second circular segment may be smaller than a semicircle. The first shape and the second shape may depend on an alignment of an actual singulation path (e.g., an actual position of a saw blade) made through the series of holes 308-2 relative to a center axis of the series of holes 308-2. For example, the actual singulation path may vary in accordance with typical manufacturing tolerances such that the actual singulation path may be aligned with the center axis of the series of holes 308-2 or may be offset from the center axis of the series of holes 308-2 in accordance with typical manufacturing tolerances.

The series of holes 308 facilitate the cutting (e.g., the sawing), since the circuit substrate assembly strip 300 has already being weakened by the series of holes 308 that extend along the first singulation paths 304. Accordingly, the series of holes 308 reduce an amount of vibration that is transferred to the circuit substrate assembly strip 300 at which the die edges are located, which reduces or prevents occurrences of substrate cracks forming at the die edges. A size, a density, and/or a pitch of the holes 308 can be optimized to remove even the slightest vibrations felt at the die edge of the die when undergoing the cutting or the sawing process. In addition, a surface within each hole 308 may be produced to have one or more different physical characteristics (e.g., roughness, etc.) that is different from a surface of a substrate edge formed as a result of the cutting or the sawing along a singulation path. For example, the creation (e.g., drilling) of a series of holes 308 and the sawing along a respective first singulation path 304 may be performed during separate manufacturing process steps, and thus a surface of the circuit substrate assembly strip 300 within each hole 308 may have one or more different physical characteristics (e.g., roughness, etc.) that is different from a surface of the circuit substrate assembly strip 300 that is formed from the sawing along the respective first singulation path 304.

It will be further appreciated that, in some implementations, the series of holes 308 may be formed along the second singulation paths 306 in addition to or alternatively to the series of holes 308 formed along the first singulation paths 304. The placement of the series of holes 308 may depend on a device configuration of the semiconductor device assembly and a placement of dies in each device region 302, with the series of holes 308 being formed, for example, when the die edges are in close proximity to the first singulation paths 304 and/or the second singulation paths 306 that are used to form the substrate edges and the package edges of the semiconductor device assemblies.

The circuit substrate assembly strip 300 may further include interconnecting pads 310, such as bond fingers or another type of bond pad or contact pad, used for providing electrical connections to the device components placed on the device regions 302.

As indicated above, FIG. 3A is provided as an example. Other examples may differ from what is described with respect to FIG. 3A.

FIG. 3B illustrates a top view diagram 312 and a perspective view diagram 314 of an example substrate edge along which a series of holes 308 is formed according to one or more implementations. As noted above in connection with FIG. 3A, the substrate edge also corresponds to a package edge of a semiconductor device assembly. The package edge is an outer boundary of the semiconductor device assembly. As a result, the substrate edge is part of the package edge (e.g., part of the outer boundary of the semiconductor device assembly).

The substrate edge shown in FIG. 3B is formed by a singulation (e.g., sawing) applied along a singulation path of a device region 302. The substrate edge includes remaining portions (e.g., concave segments or circular segments) of the series of holes 308. Thus, the substrate edge may be referred to as a circular segmented edge. Accordingly, the substrate edge includes a series of concave segments or circular segments that are provided along a length of the substrate edge. In other words, the substrate edge is perforated by the remaining portions of the series of holes 308.

As described above in connection with FIG. 3A, the remaining portion of the series of holes 308 has a shape that may be defined by a circular segment. The circular segment has a perimeter bounded by an arc (e.g., a concaved edge) and a chord of a circle (e.g., a straight edge of the substrate edge).

As indicated above, FIG. 3B is provided as an example. Other examples may differ from what is described with respect to FIG. 3B.

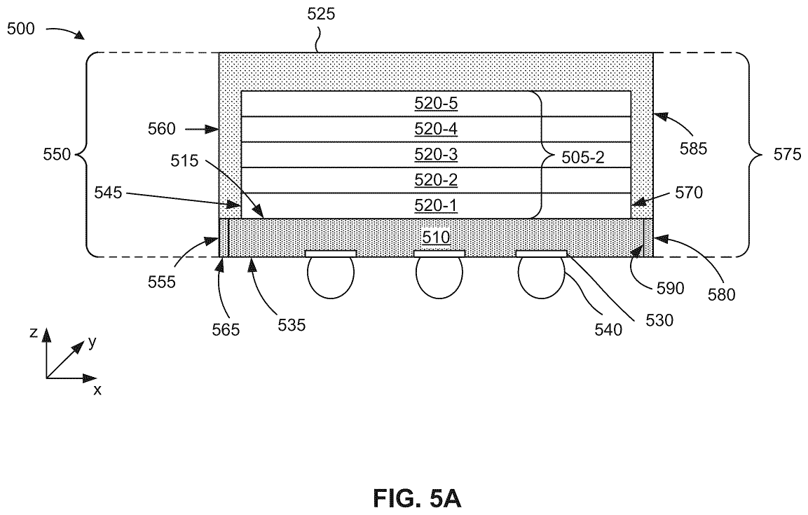

FIG. 4 illustrates a front view of an example semiconductor device assembly 400 that may be manufactured using techniques described herein according to one or more implementations. The semiconductor device assembly 400 is an example of the apparatus 100 described above in connection with FIG. 1. In some implementations, the semiconductor device assembly 400 may be a semiconductor package assembly.

The semiconductor device assembly 400 may include any type of device or system that includes one or more integrated circuits 405. For example, the semiconductor device assembly 400 may include a memory device, a flash memory device, a NAND memory device, a NOR memory device, a RAM device, a ROM device, a DRAM device, an SRAM device, an SSD, a microchip, and/or an SoC device, among other examples. In some cases, the semiconductor device assembly 400 may be referred to as a semiconductor package, a semiconductor chip package, an assembly, or an integrated assembly. In some cases, the semiconductor device assembly 400 may be a memory device that includes at least one memory die.

As shown in FIG. 4, the semiconductor device assembly 400 may include one or more integrated circuits 405, shown as a first integrated circuit 405-1 and a second integrated circuit 405-2, disposed on a circuit substrate 410, such as a PCB. An integrated circuit 405 may be mounted on or otherwise disposed on a first substrate surface 415 of the circuit substrate 410. In some implementations, the first integrated circuit 405-1 may be a control device, such as a controller or a power management IC. Although the semiconductor device assembly 400 is shown as including two integrated circuits 405 as an example, the semiconductor device assembly 400 may include a different number of integrated circuits 405.

In some implementations, an integrated circuit 405 may be a single die. For example, the first integrated circuit 405-1 may be a single die. In some implementations, an integrated circuit 405 may include multiple semiconductor dies 420, shown as five semiconductor dies 420-1 through 420-5. In some implementations, the dies 420-1 through 420-5 may be memory devices, such as flash memory dies, and the first integrated circuit 405-1 may be a memory controller configured to perform read/write operations with the dies 420-1 through 420-5. However, it will be appreciated that the dies 420-1 through 420-5 may be any type of device, including those devices mentioned above.

The semiconductor device assembly 400 may include a casing 425 (e.g., a package casing) that protects internal components of the semiconductor device assembly 400 (e.g., the integrated circuits 405) from damage and environmental elements (e.g., particles) that can lead to malfunction of the semiconductor device assembly 400. The casing 425 is disposed over the first substrate surface 415 to encapsulate the integrated circuits 405. The casing 425 may also partially or fully encapsulate the first substrate surface 415. The casing 425 may be a package molding, a mold compound, a plastic (e.g., an epoxy plastic), a ceramic, or another type of material depending on the functional requirements for the semiconductor device assembly 400.

The circuit substrate 410 may include internal conductive structures (e.g., redistribution layers) embedded therein and electrical contacts 430 arranged at a second substrate surface 435 of the circuit substrate 410. The internal conductive structures may be connected to the electrical contacts 430 to be electrically connected to an external device. The semiconductor device assembly 400 may further include solder balls 440, or another type of connector, electrically connected to the electrical contacts 430. The solder balls 440 may be used for mounting the semiconductor device assembly 400 to, for example, a carrier substrate or to an external device.

The first integrated circuit 405-1 has a die edge 445 arranged proximate to a first package edge 450 of the semiconductor device assembly 400. The first package edge 450 is formed by a first substrate edge 455 positioned at a first side of the circuit substrate 410 and a first casing edge 460 positioned at a first side of the casing 425. The first substrate edge 455 extends along a z-axis between the first substrate surface 415 and the second substrate surface 435. In some implementations, the first substrate edge 455 is coincident with the first casing edge 460, as shown in FIG. 4.

Prior to singulation, the first package edge 450 is arranged along a first singulation path. The first package edge 450 is formed by cutting through the casing 425 and the circuit substrate 410 along the first singulation path, for example, by sawing. The first substrate edge 455 includes a first series of holes 465 that are arranged along the first substrate edge 455. Each hole 465 extends at least partially from the first substrate surface 415 toward the second substrate surface 435. Each hole 465 is a remaining portion of a series of holes (e.g., series of holes 308 formed in a circuit substrate assembly strip (e.g., circuit substrate assembly strip 300)). The first series of holes 465 may be blind holes or through-holes, each having a circular segment shape.

A size, a density, and/or a pitch of the holes 308 can be optimized to remove even the slightest vibrations felt at the die edge 445 when undergoing the singulation process. In addition, a surface within each hole 465 may be produced to have one or more different physical characteristics (e.g., roughness, etc.) that is different from a surface of the first substrate edge 455 formed as a result of the singulation performed along the first singulation path. For example, a roughness of the surface the first substrate edge 455 produced by sawing may be different than a roughness of the surface within each hole 465 produced by boring used to produce holes 308. For example, the creation (e.g., drilling) of a series of holes 308 formed along the first singulation path and the sawing along the first singulation path may be performed during separate manufacturing process steps, and thus a surface circuit substrate 410 within each hole 308 may have one or more different physical characteristics (e.g., roughness, etc.) that is different from a surface of the first substrate edge 455 that is formed from the sawing along the first singulation path.

Moreover, the casing 425 extends into each of the first series of holes 465, thereby filling each of the first series of holes 465. For example, a casing material used to form the casing 425 may be applied to the first substrate surface 415 prior to singulation. As a result, the casing material is not only disposed onto the first substrate surface 415 and over the integrated circuits 405, but the casing material is also disposed within the series of holes (e.g., series of hole 308) formed in the circuit substrate assembly strip. A portion of the casing material disposed within the series of holes remains within the first series of holes 465 after singulation as part of the casing 425, and, more particularly, as part of the first package edge 450. Therefore, the casing 425 is mechanically interlocked with the first substrate edge 455. This may provide additional structural support and protection to the circuit substrate 410 at the first substrate edge 455 (e.g., at the first package edge 450).

The die 420-1 has a die edge 470 arranged proximate to a second package edge 475 of the semiconductor device assembly 400. The second package edge 475 is formed by a second substrate edge 480 positioned at a second side of the circuit substrate 410 and a second casing edge 485 positioned at a second side of the casing 425. The second substrate edge 480 extends along the z-axis between the first substrate surface 415 and the second substrate surface 435. In some implementations, the second substrate edge 480 is coincident with the second casing edge 485, as shown in FIG. 4.

Prior to singulation, the second package edge 475 is arranged along a second singulation path. The second package edge 475 is formed by cutting through the casing 425 and the circuit substrate 410 along the second singulation path (for example, by sawing). The second substrate edge 480 includes a second series of holes 490 that are arranged along the second substrate edge 480. Each hole 490 extends at least partially from the first substrate surface 415 toward the second substrate surface 435. Each hole 490 is a remaining portion of a series of holes (e.g., a series of holes 308 formed in a circuit substrate assembly strip (e.g., circuit substrate assembly strip 300)). The second series of holes 490 may be blind holes or through-holes, each having a circular segment shape.

A size, a density, and/or a pitch of the holes 308 can be optimized to remove even the slightest vibrations felt at the die edge 470 when undergoing the singulation process. In addition, a surface within each hole 490 may be produced to have one or more different physical characteristics (e.g., roughness, etc.) that is different from a surface of the second substrate edge 480 formed as a result of the singulation performed along the second singulation path. For example, a roughness of the surface the second substrate edge 480 produced by sawing may be different than a roughness of the surface within each hole 490 produced by boring used to produce holes 308. For example, the creation (e.g., drilling) of a series of holes 308 formed along the second singulation path and the sawing along the second singulation path may be performed during separate manufacturing process steps, and thus a surface circuit substrate 410 within each hole 308 may have one or more different physical characteristics (e.g., roughness, etc.) that is different from a surface of the second substrate edge 480 that is formed from the sawing along the second singulation path.

Moreover, the casing 425 extends into each of the second series of holes 490, thereby filling each of the second series of holes 490. For example, the casing material used to form the casing 425 may be applied to the first substrate surface 415 prior to the singulation. As a result, the casing material is not only disposed onto the first substrate surface 415 and over the integrated circuits 405, but the casing material is also disposed within the series of holes (e.g., series of hole 308) formed in the circuit substrate assembly strip. A portion of the casing material disposed within the series of holes remains within the second series of holes 490 after singulation as part of the casing 425, and, more particularly, as part of the second package edge 475. Therefore, the casing 425 is mechanically interlocked with the second substrate edge 480. This may provide additional structural support and protection to the circuit substrate 410 at the second substrate edge 480 (e.g., at the second package edge 475).

As indicated above, FIG. 4 is provided as an example. Other examples may differ from what is described with regard to FIG. 4. The number and arrangement of components shown in FIG. 4 are provided as an example. In practice, there may be additional components, fewer components, different components, or differently arranged components than those shown in FIG. 4.

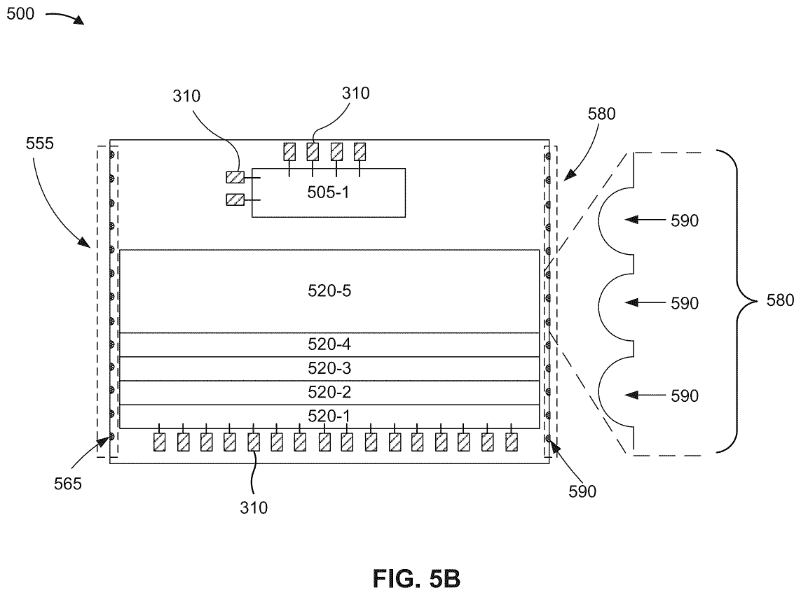

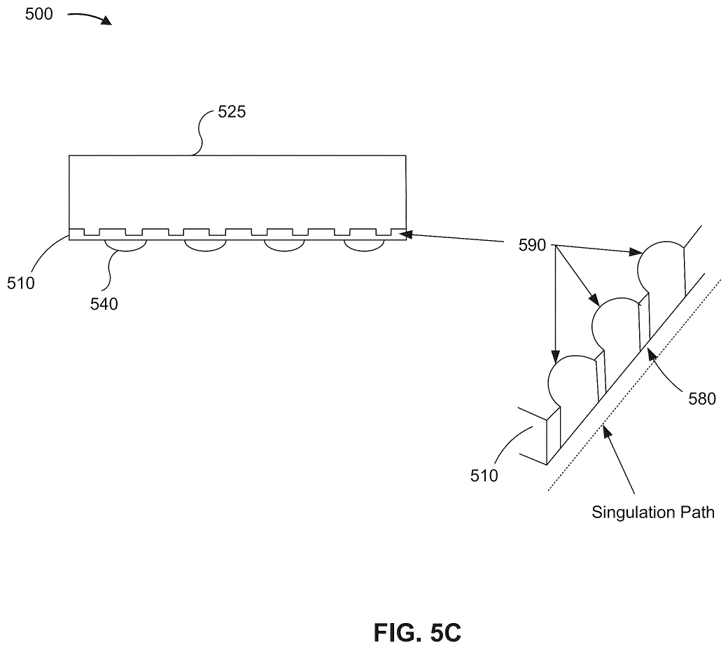

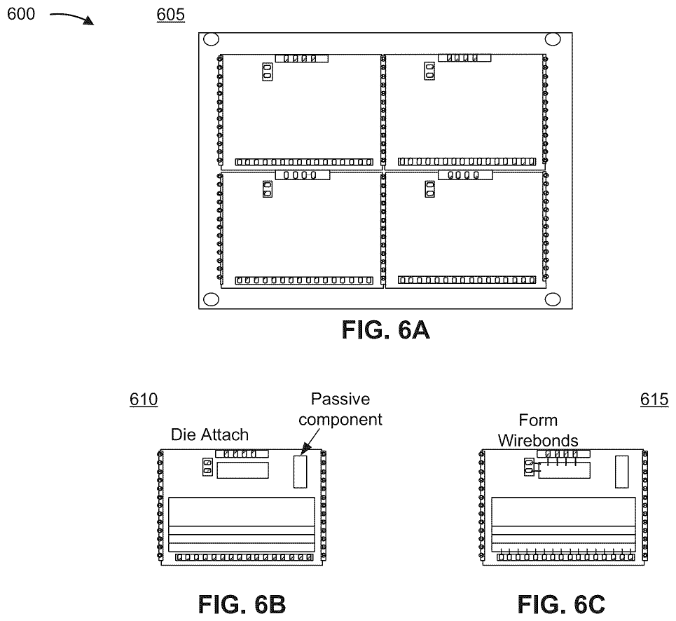

FIG. 5A illustrates a front view of an example semiconductor device assembly 500 that may be manufactured using techniques described herein according to one or more implementations. In some implementations, the semiconductor device assembly 500 may be a semiconductor package assembly.

FIG. 5B illustrates a top view of the semiconductor device assembly 500 according to one or more implementations.

FIG. 5C illustrates a side view of the semiconductor device assembly 500 according to one or more implementations.

The semiconductor device assembly 500 is an example of the apparatus 100 described above in connection with FIG. 1. The semiconductor device assembly 500 may be considered a more compact version of the semiconductor device assembly 400. For example, the semiconductor device assembly 500 may include at least one die that includes a first die edge arranged laterally from a first substrate edge by 100 μm or less and a second die edge arranged opposite to the first die edge and arranged laterally from a second substrate edge by 100 μm or less. Accordingly, a die may have both die edges in close proximity to one of the substrate edges. In some implementations, the first die edge and/or the second die edge may be arranged more than 100 μm from the first substrate edge and the second substrate edge, respectively, and still be considered to be within close proximity to a substrate edge.

The semiconductor device assembly 500 may include any type of device or system that includes one or more integrated circuits 505. For example, the semiconductor device assembly 500 may include a memory device, a flash memory device, a NAND memory device, a NOR memory device, a RAM device, a ROM device, a DRAM device, an SRAM device, an SSD, a microchip, and/or a SoC device, among other examples. In some cases, the semiconductor device assembly 500 may be referred to as a semiconductor package, a semiconductor chip package, an assembly, or an integrated assembly. In some cases, the semiconductor device assembly 500 may be a memory device that includes at least one memory die.

As shown in FIGS. 5A and 5B, the semiconductor device assembly 500 may include one or more integrated circuits 505, shown as a first integrated circuit 505-1 in FIG. 5B and a second integrated circuit 505-2 in FIGS. 5A and 5B, disposed on a circuit substrate 510, such as a PCB. An integrated circuit 505 may be mounted on or otherwise disposed on a first substrate surface 515 of the circuit substrate 510. In some implementations, the first integrated circuit 505-1 may be a control device, such as a controller or a power management IC. Although the semiconductor device assembly 500 is shown as including two integrated circuits 505 as an example, the semiconductor device assembly 500 may include a different number of integrated circuits 505.

In some implementations, an integrated circuit 505 may be a single die. For example, the first integrated circuit 505-1 may be a single die. In some implementations, an integrated circuit 505 may include multiple semiconductor dies 520, shown as five semiconductor dies 520-1 through 520-5. In some implementations, the dies 520-1 through 520-5 may be memory devices, such as flash memory dies, and the first integrated circuit 505-1 may be a memory controller configured to perform read/write operations with the dies 520-1 through 520-5. However, it will be appreciated that the dies 520-1 through 520-5 may be any type of device, including those devices mentioned above.

The semiconductor device assembly 500 may include a casing 525 (e.g., a package casing) that protects internal components of the semiconductor device assembly 500 (e.g., the integrated circuits 505) from damage and environmental elements (e.g., particles) that can lead to malfunction of the semiconductor device assembly 500. The casing 525 is disposed over the first substrate surface 515 to encapsulate the integrated circuits 505. The casing 525 may also partially or fully encapsulate the first substrate surface 515. The casing 525 may be a package molding, a mold compound, a plastic (e.g., an epoxy plastic), a ceramic, or another type of material depending on the functional requirements for the semiconductor device assembly 500.

The circuit substrate 510 may include internal conductive structures (e.g., redistribution layers) embedded therein and electrical contacts 530 arranged at a second substrate surface 535 of the circuit substrate 510. The internal conductive structures may be connected to the electrical contacts 530 to be electrically connected to an external device. The semiconductor device assembly 500 may further include solder balls 540, or another type of connector, electrically connected to the electrical contacts 530. The solder balls 540 may be used for mounting the semiconductor device assembly 500 to, for example, a carrier substrate or to an external device.

The die 520-1 may have a first die edge 545 arranged proximate to a first package edge 550 of the semiconductor device assembly 500. The first package edge 550 may be formed by a first substrate edge 555 positioned at a first side of the circuit substrate 510 and a first casing edge 560 positioned at a first side of the casing 525. The first substrate edge 555 may extend along a z-axis between the first substrate surface 515 and the second substrate surface 535. In some implementations, the first substrate edge 555 may be coincident with the first casing edge 560, as shown in FIG. 5A.

Prior to singulation, the first package edge 550 is arranged along a first singulation path. The first package edge 550 may be formed by cutting through the casing 525 and the circuit substrate 510 along the first singulation path, for example, by sawing. The first substrate edge 555 may include a first series of holes 565 that are arranged along the first substrate edge 555. Each hole 565 extends at least partially from the first substrate surface 515 toward the second substrate surface 535. Each hole 565 is a remaining portion of a series of holes (e.g., series of holes 308 formed in a circuit substrate assembly strip (e.g., circuit substrate assembly strip 300)). The first series of holes 565 may be blind holes or through-holes, each having a circular segment shape.

Moreover, the casing 525 may extend into each of the first series of holes 565, thereby filling each of the first series of holes 565. For example, a casing material used to form the casing 525 may be applied to the first substrate surface 515 prior to singulation. As a result, the casing material is not only disposed onto the first substrate surface 515 and over the integrated circuits 505, but the casing material is also disposed within the series of holes (e.g., series of hole 308) formed in the circuit substrate assembly strip. A portion of the casing material disposed within the series of holes remains within the first series of holes 565 after singulation as part of the casing 525, and, more particularly, as part of the first package edge 550. Therefore, the casing 525 may be mechanically interlocked with the first substrate edge 555. This may provide additional structural support and protection to the circuit substrate 510 at the first substrate edge 555 (e.g., at the first package edge 550).

The die 520-1 may have a second die edge 570 arranged proximate to a second package edge 575 of the semiconductor device assembly 500. The second package edge 575 may be formed by a second substrate edge 580 positioned at a second side of the circuit substrate 510 and a second casing edge 585 positioned at a second side of the casing 525. The second substrate edge 580 may extend along the z-axis between the first substrate surface 515 and the second substrate surface 535. In some implementations, the second substrate edge 580 may be coincident with the second casing edge 585, as shown in FIG. 5A.

Prior to singulation, the second package edge 575 is arranged along a second singulation path. The second package edge 575 may be formed by cutting through the casing 525 and the circuit substrate 510 along the second singulation path (for example, by sawing). The second substrate edge 580 may include a second series of holes 590 that are arranged along the second substrate edge 580. Each hole 590 extends at least partially from the first substrate surface 515 toward the second substrate surface 535. Each hole 590 is a remaining portion of a series of holes (e.g., series of holes 308 formed in a circuit substrate assembly strip (e.g., circuit substrate assembly strip 300)). The second series of holes 590 may be blind holes or through-holes, each having a circular segment shape.

Moreover, the casing 525 may extend into each of the second series of holes 590, thereby filling each of the second series of holes 590. For example, the casing material used to form the casing 525 may be applied to the first substrate surface 515 prior to the singulation. As a result, the casing material is not only disposed onto the first substrate surface 515 and over the integrated circuits 505, but the casing material is also disposed within the series of holes (e.g., series of hole 308) formed in the circuit substrate assembly strip. A portion of the casing material disposed within the series of holes remains within the second series of holes 590 after singulation as part of the casing 525, and, more particularly, as part of the second package edge 575. Therefore, the casing 525 is mechanically interlocked with the second substrate edge 580. This may provide additional structural support and protection to the circuit substrate 510 at the second substrate edge 580 (e.g., at the second package edge 575).

The top view of the semiconductor device assembly 500 shown in FIG. 5B shows the first series of holes 565 arranged along the first substrate edge 555 and the second series of holes 590 arranged along the second substrate edge 580. On the right side of FIG. 5B, a zoomed-in portion of the second substrate edge 580 is shown. As illustrated in this zoomed-in portion of the second substrate edge 580, each hole of the second series of holes 590 defines a respective concaved segment of the second substrate edge 580. Similarly, each hole of the first series of holes 565 defines a respective concaved segment of the first substrate edge 555.

The side view of the semiconductor device assembly 500 shown in FIG. 5C shows the second package edge 575 of the semiconductor device assembly 500. The casing 525 fills each of the second series of holes 590 and is mechanically interlocked with the second substrate edge 580. Filling the holes 590 with the casing material of the casing 525 may provide additional structural support and protection to the circuit substrate 510 at the second substrate edge 580 (e.g., at the second package edge 575).

In this example, the second series of holes 590 are blind holes. In other words, the second series of holes 590 extend partially (e.g., not fully) from the first substrate surface 515 to the second substrate surface 535. Accordingly, a bottom of each hole 590 is defined by the circuit substrate 510 that remains after forming the second series of holes 590. In this example, the casing 525 is in direct contact with the circuit substrate 510 at the bottom of each hole 590. Using blind holes may increase an amount of surface area at which the casing 525 and the circuit substrate 510 are in contact with each other, which may lead to better bonding contact and/or higher bond strength between the casing 525 and the circuit substrate 510 and improved structural integrity of the semiconductor device assembly 500 (e.g., of the package).

In some implementations, using through-holes for a series of holes (e.g., holes 565 and 590) may allow the casing material of the casing 525 to pass through the circuit substrate 510 and form over part of the second substrate surface 535. As a result, the casing 525 may be bonded to the second substrate surface 535 to improve the bonding between the casing 525 and the circuit substrate 510 and improve the structural integrity of the semiconductor device assembly 500 (e.g., of the package).

The circuit substrate 510 may include a solder mask formed on the first substrate surface 515 to cover the first substrate surface 515. The solder mask provides protection to conductive traces of the circuit substrate 510 formed at the first substrate surface 515 and prevents solder bridges from forming between closely spaced contact pads. However, the solder mask may decrease the bonding strength of the casing 525 to the circuit substrate 510.

Accordingly, in some implementations, the solder mask may be removed from edge areas of the first substrate surface 515 at the first substrate edge 555 and the second substrate edge 580 such that the first substrate surface 515 is exposed. With the solder mask being absent from these edge areas, the casing 525 can make direct contact with the first substrate surface 515 (e.g., to a prepreg layer or a core layer of the circuit substrate 510), which may allow better bonding of the casing 525 to the circuit substrate.

As indicated above, FIGS. 5A-5C are provided as examples. Other examples may differ from what is described with regard to FIGS. 5A-5C. The number and arrangement of components shown in FIGS. 5A-5C are provided as an example. In practice, there may be additional components, fewer components, different components, or differently arranged components than those shown in FIGS. 5A-5C.

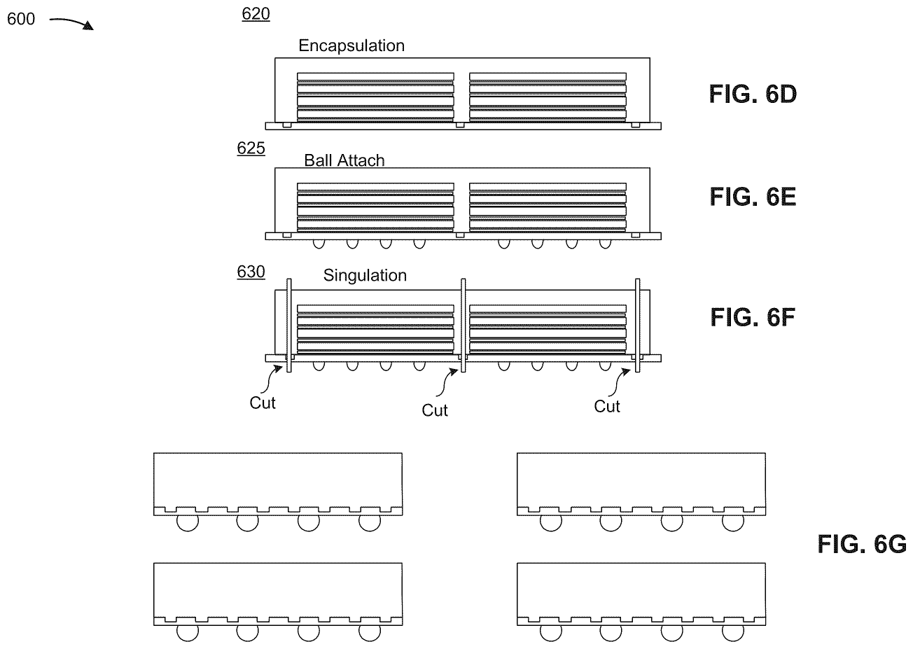

FIGS. 6A-6G illustrate a process flow of an example method 600 of forming one or more semiconductor device assemblies. In some implementations, one or more process operations of FIGS. 6A-6G may be performed by various semiconductor manufacturing equipment.

As shown in FIG. 6A, the method 600 may include a fabricating process 605, including fabricating a circuit substrate assembly strip having a plurality of device regions, and forming a plurality of series of holes along singulation paths used for singulating the plurality of device regions. Thus, each device region may be delineated by a series of holes arranged along a respective singulation path, where each hole of the series of holes extends at least partially through the circuit substrate assembly strip. In some cases, adjacent device regions share a series of holes at a common boundary (e.g., at a common or shared singulation path). In some implementations, interconnection pads may also be formed in each device region.

As shown in FIG. 6B, the method 600 may include a die attach process 610, including attaching at least one die to each device region of the circuit substrate assembly strip. In some implementations, one or more passive components may also be attached to each device region of the circuit substrate assembly strip.

As shown in FIG. 6C, the method 600 may include a wire bonding process 615, including forming wire bonds between the dies and the interconnection pads in each device region.

As shown in FIG. 6D, the method 600 may include an encapsulation process 620, including depositing a casing material on a top surface of the circuit substrate assembly strip. Depositing a casing material may include depositing the casing material over the dies in each of the device regions and over each of the singulation paths in order to encapsulate the dies in each of the device regions and to encapsulate each of the circulation paths. Depositing a casing material includes filling each of the series of holes with the casing material. The casing material may then be cured to form a casing (e.g., a package casing).

As shown in FIG. 6E, the method 600 may include a ball attach process 625, including attaching solder balls to a bottom surface of the circuit substrate assembly strip.

As shown in FIG. 6F, the method 600 may include a singulation process 630, including cutting through (e.g., sawing through) the casing material and the circuit substrate assembly strip along each of the singulation paths to separate each of the device regions from each other to form a semiconductor device assembly corresponding to each device region. The singulation operation forms package edges of each of the semiconductor package assemblies. The casing material deposited in the series of holes forms a portion of the package edges for the respective semiconductor package assemblies.

As shown in FIG. 6G, a separate semiconductor device assembly is produced for each device region of the circuit substrate assembly strip. The casing material is mechanically interlocked with a circuit substrate of each semiconductor device assembly along a substrate edge that coincides with a package edge.

The method 600 may include additional aspects, such as any single aspect or any combination of aspects described below and/or in connection with one or more other methods described elsewhere herein.

Although FIG. 6 shows example blocks of the method 600, in some implementations, the method 600 may include additional processes, fewer processes, different processes, or differently arranged processes than those depicted in FIG. 6. In some implementations, the method 600 may include forming the structure of the circuit substrate assembly strip and/or the structure of the semiconductor device assembly (e.g., semiconductor device assembly 400 or 500), an integrated assembly that includes the semiconductor device assembly (e.g., semiconductor device assembly 400 or 500), and electronic system assembly that includes the semiconductor device assembly (e.g., semiconductor device assembly 400 or 500), any part described herein of the circuit substrate assembly strip and/or the structure of the semiconductor device assembly (e.g., semiconductor device assembly 400 or 500), and/or any part described herein of an integrated assembly that includes the semiconductor device assembly (e.g., semiconductor device assembly 400 or 500). For example, the method 600 may include forming one or more of the parts of the circuit substrate assembly strip 300, the semiconductor device assembly 400, or the semiconductor device assembly 500.

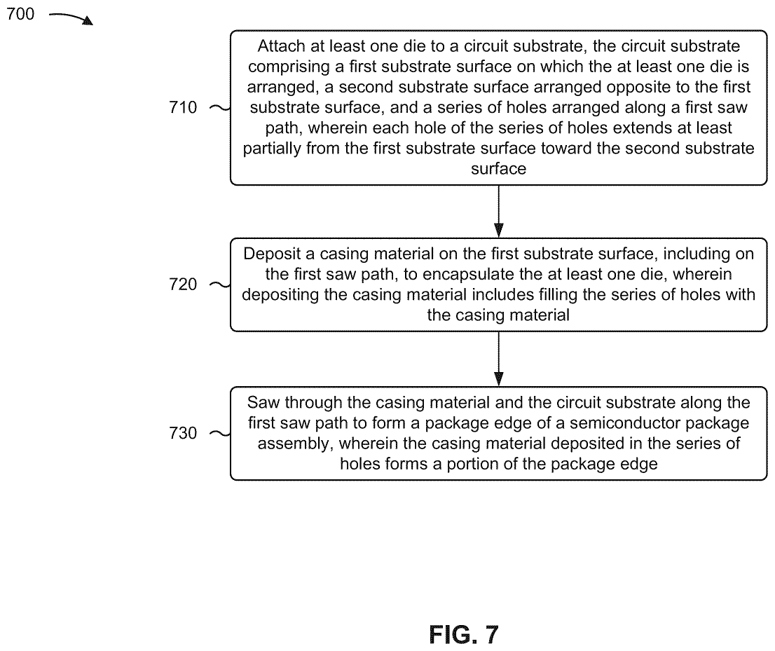

FIG. 7 is a flowchart of an example method 700 of forming an integrated assembly or memory device having a semiconductor package assembly with a circular segmented package edge. In some implementations, one or more process blocks of FIG. 7 may be performed by various semiconductor manufacturing equipment.

As shown in FIG. 7, the method 700 may include attaching at least one die to a circuit substrate, the circuit substrate comprising a first substrate surface on which the at least one die is arranged, a second substrate surface arranged opposite to the first substrate surface, and a series of holes arranged along a first saw path, wherein each hole of the series of holes extends at least partially from the first substrate surface toward the second substrate surface (block 710).

As further shown in FIG. 7, the method 700 may include depositing a casing material on the first substrate surface, including on the first saw path, to encapsulate the at least one die, wherein depositing the casing material includes filling the series of holes with the casing material (block 720).

As further shown in FIG. 7, the method 700 may include sawing through the casing material and the circuit substrate along the first saw path to form a package edge of a semiconductor package assembly, wherein the casing material deposited in the series of holes forms a portion of the package edge (block 730).

The method 700 may include additional aspects, such as any single aspect or any combination of aspects described below and/or in connection with one or more other methods described elsewhere herein.

In a first aspect, the method 700 includes sawing through the casing material and the circuit substrate along the first saw path to form a substrate edge of the circuit substrate as part of the package edge, and the casing material is mechanically interlocked with the circuit substrate along the substrate edge.

In a second aspect, alone or in combination with the first aspect, the substrate edge of the semiconductor package assembly includes a remaining portion of each hole of the series of holes, and the remaining portion of each hole of the series of holes has a perimeter defined by a circular segment.

In a third aspect, alone or in combination with one or more of the first and second aspects, each hole of the series of holes extends partially from the first substrate surface to the second substrate surface.

In a fourth aspect, in combination with the third aspect, a bottom of each hole of the series of holes is defined by the circuit substrate, and the casing material is in direct contact with the circuit substrate along the bottom of each hole of the series of holes.

In a fifth aspect, alone or in combination with one or more of the first through second aspects, each hole of the series of holes extends entirely from the first substrate surface to the second substrate surface.

Although FIG. 7 shows example blocks of the method 700, in some implementations, the method 700 may include additional blocks, fewer blocks, different blocks, or differently arranged blocks than those depicted in FIG. 7. In some implementations, the method 700 may include forming the structure of the circuit substrate assembly strip and/or the structure of the semiconductor device assembly (e.g., semiconductor device assembly 400 or 500), an integrated assembly that includes the semiconductor device assembly (e.g., semiconductor device assembly 400 or 500), and electronic system assembly that includes the semiconductor device assembly (e.g., semiconductor device assembly 400 or 500), any part described herein of the circuit substrate assembly strip and/or the structure of the semiconductor device assembly (e.g., semiconductor device assembly 400 or 500), and/or any part described herein of an integrated assembly that includes the semiconductor device assembly (e.g., semiconductor device assembly 400 or 500). For example, the method 700 may include forming one or more of the parts of the circuit substrate assembly strip 300, the semiconductor device assembly 400, or the semiconductor device assembly 500, including, but not limited to, parts 308, 425, 450, 455, 460, 465, 475, 480, 485, 490, 550, 555, 560, 565, 575, 580, 585, and 590.

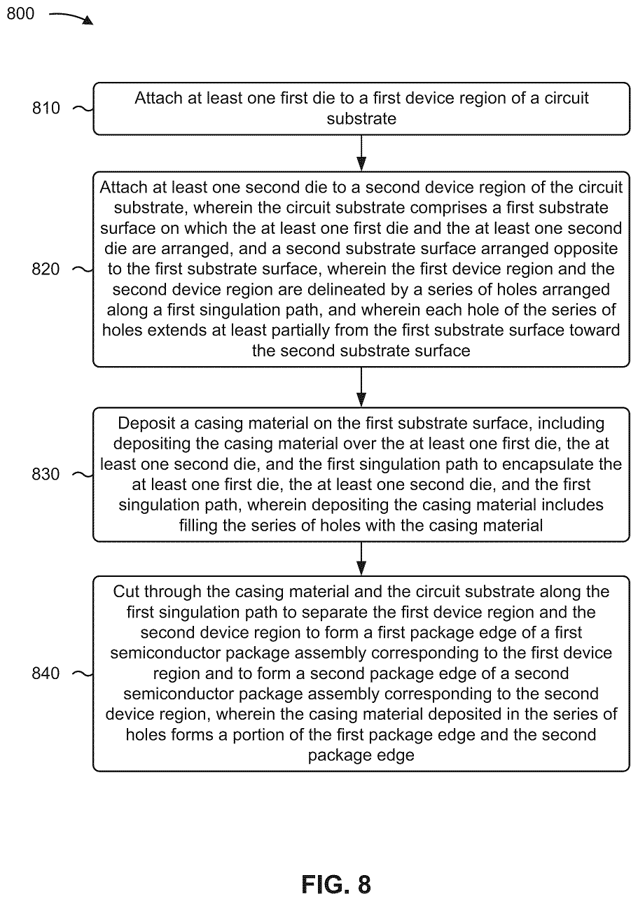

FIG. 8 is a flowchart of an example method 800 of forming an integrated assembly or memory device having a semiconductor package assembly with a circular segmented package edge. In some implementations, one or more process blocks of FIG. 8 may be performed by various semiconductor manufacturing equipment.

As shown in FIG. 8, the method 800 may include attaching at least one first die to a first device region of a circuit substrate (block 810).

As further shown in FIG. 8, the method 800 may include attaching at least one second die to a second device region of the circuit substrate, wherein the circuit substrate comprises a first substrate surface on which the at least one first die and the at least one second die are arranged, and a second substrate surface arranged opposite to the first substrate surface, wherein the first device region and the second device region are delineated by a series of holes arranged along a first singulation path, and wherein each hole of the series of holes extends at least partially from the first substrate surface toward the second substrate surface (block 820).

As further shown in FIG. 8, the method 800 may include depositing a casing material on the first substrate surface, including depositing the casing material over the at least one first die, the at least one second die, and the first singulation path to encapsulate the at least one first die, the at least one second die, and the first singulation path, wherein depositing the casing material includes filling the series of holes with the casing material (block 830).

As further shown in FIG. 8, the method 800 may include cutting through the casing material and the circuit substrate along the first singulation path to separate the first device region and the second device region to form a first package edge of a first semiconductor package assembly corresponding to the first device region and to form a second package edge of a second semiconductor package assembly corresponding to the second device region, wherein the casing material deposited in the series of holes forms a portion of the first package edge and the second package edge (block 840).

The method 800 may include additional aspects, such as any single aspect or any combination of aspects described below and/or in connection with one or more other methods described elsewhere herein.

In a first aspect, the method 800 includes cutting through the casing material and the circuit substrate along the first singulation path forms a first substrate edge of the circuit substrate as part of the first package edge and forms a second substrate edge of the circuit substrate as part of the second package edge, the casing material is mechanically interlocked with the circuit substrate of the first semiconductor package assembly along the first substrate edge, and the casing material is mechanically interlocked with the circuit substrate of the second semiconductor package assembly along the second substrate edge.

In a second aspect, alone or in combination with the first aspect, the first substrate edge of the first semiconductor package assembly includes a first remaining portion of each hole of the series of holes, and the first remaining portion of each hole of the series of holes has a first shape defined by a first circular segment, and the second substrate edge of the second semiconductor package assembly includes a second remaining portion of each hole of the series of holes, and the second remaining portion of each hole of the series of holes has a second shape defined by a second circular segment.

In a third aspect, alone or in combination with one or more of the first and second aspects, the series of holes is a first series of holes, wherein the first device region is further delineated by a second series of holes arranged along a second singulation path, wherein each hole of the second series of holes extends at least partially from the first substrate surface toward the second substrate surface, wherein the second device region is further delineated by a third series of holes arranged along a third singulation path, wherein each hole of the third series of holes extends at least partially from the first substrate surface toward the second substrate surface, wherein depositing the casing material on the first substrate surface further comprises depositing the casing material over the second singulation path and the third singulation path to encapsulate the second singulation path and the third singulation path, wherein depositing the casing material on the first substrate surface further comprises filling the second series of holes and the third series of holes with the casing material, wherein the method 800 further comprises cutting through the casing material and the circuit substrate along the second singulation path to form a third package edge of the first semiconductor package assembly, wherein the casing material deposited in the second series of holes forms a portion of the third package edge, and cutting through the casing material and the circuit substrate along the third singulation path to form a fourth package edge of the second semiconductor package assembly, wherein the casing material deposited in the third series of holes forms a portion of the fourth package edge.

In a fourth aspect, alone or in combination with one or more of the first through third aspects, the first singulation path, the second singulation path, and the third singulation path extend parallel to each other.

Although FIG. 8 shows example blocks of the method 800, in some implementations, the method 800 may include additional blocks, fewer blocks, different blocks, or differently arranged blocks than those depicted in FIG. 8. In some implementations, the method 800 may include forming the structure of the circuit substrate assembly strip and/or the structure of the semiconductor device assembly (e.g., semiconductor device assembly 400 or 500), an integrated assembly that includes the semiconductor device assembly (e.g., semiconductor device assembly 400 or 500), and electronic system assembly that includes the semiconductor device assembly (e.g., semiconductor device assembly 400 or 500), any part described herein of the circuit substrate assembly strip and/or the structure of the semiconductor device assembly (e.g., semiconductor device assembly 400 or 500), and/or any part described herein of an integrated assembly that includes the semiconductor device assembly (e.g., semiconductor device assembly 400 or 500). For example, the method 800 may include forming one or more of the parts of the circuit substrate assembly strip 300, the semiconductor device assembly 400, or the semiconductor device assembly 500, including, but not limited to, parts 308, 425, 450, 455, 460, 465, 475, 480, 485, 490, 550, 555, 560, 565, 575, 580, 585, and 590.

The following provides an overview of some Aspects of the present disclosure:

Aspect 1: A semiconductor device assembly, comprising: a circuit substrate comprising a first substrate surface, a second substrate surface arranged opposite to the first substrate surface, a first substrate edge that extends from the first substrate surface to the second substrate surface, and a second substrate edge that extends from the first substrate surface to the second substrate surface and is arranged opposite to the first substrate edge; a series of holes arranged along the first substrate edge of the circuit substrate, wherein each hole of the series of holes extends at least partially from the first substrate surface toward the second substrate surface; at least one die arranged on the first substrate surface; and a package casing disposed over the first substrate surface, wherein the package casing encapsulates the at least one die and the first substrate surface, and wherein the package casing fills each hole of the series of holes.

Aspect 2: The semiconductor device assembly of Aspect 1, wherein the package casing is mechanically interlocked with the first substrate edge.

Aspect 3: The semiconductor device assembly of any of Aspects 1-2, wherein the first substrate edge is a perforated edge formed with the series of holes.

Aspect 4: The semiconductor device assembly of any of Aspects 1-3, wherein each hole of the series of holes defines a respective concaved segment of the first substrate edge.

Aspect 5: The semiconductor device assembly of any of Aspects 1-4, wherein each hole of the series of holes has a perimeter having a substantially semicircular shape.

Aspect 6: The semiconductor device assembly of any of Aspects 1-5, wherein each hole of the series of holes extends partially from the first substrate surface to the second substrate surface.

Aspect 7: The semiconductor device assembly of Aspect 6, wherein: a bottom of each hole of the series of holes is defined by the circuit substrate, and the package casing is in direct contact with the circuit substrate at the bottom of each hole of the series of holes.

Aspect 8: The semiconductor device assembly of any of Aspects 1-7, wherein each hole of the series of holes extends entirely from the first substrate surface to the second substrate surface.

Aspect 9: The semiconductor device assembly of any of Aspects 1-8, wherein: the circuit substrate comprises a solder mask formed on the first substrate surface to cover the first substrate surface, wherein the first substrate surface is exposed at the first substrate edge, with the solder mask being absent therefrom, and the package casing is in direct contact with the first substrate surface at the first substrate edge.

Aspect 10: The semiconductor device assembly of Aspect 9, wherein the first substrate surface is a prepreg layer or a core layer.

Aspect 11: The semiconductor device assembly of any of Aspects 1-10, wherein: the series of holes is a first series of holes, and the semiconductor device assembly further comprises: a second series of holes arranged along the second substrate edge of the circuit substrate, wherein each hole of the second series of holes extends at least partially from the first substrate surface toward the second substrate surface, wherein the package casing fills the second series of holes. a second series of holes arranged along the second substrate edge of the circuit substrate, wherein each hole of the second series of holes extends at least partially from the first substrate surface toward the second substrate surface, wherein the package casing fills the second series of holes.

Aspect 12: The semiconductor device assembly of Aspect 11, wherein the package casing is mechanically interlocked with the first substrate edge and the second substrate edge.

Aspect 13: The semiconductor device assembly of Aspect 11, wherein the first substrate edge is a first perforated edge formed with the first series of holes and the second substrate edge is a second perforated edge formed with the second series of holes.

Aspect 14: The semiconductor device assembly of Aspect 11, wherein each hole of the first series of holes and each hole of the second series of holes has a perimeter bounded by an arc and a chord of a circle.

Aspect 15: The semiconductor device assembly of Aspect 11, wherein the first substrate edge corresponds to a first saw path and the second substrate edge corresponds to a second saw path.

Aspect 16: The semiconductor device assembly of any of Aspects 1-15, wherein the at least one die includes a plurality of dies arranged in a stacked configuration, wherein the at least one die includes a die edge arranged laterally from the first substrate edge by 100 micrometers or less.

Aspect 17: The semiconductor device assembly of Aspect 16, wherein the plurality of dies are flash memory dies.

Aspect 18: A memory device, comprising: a circuit substrate comprising a first substrate surface, a second substrate surface arranged opposite to the first substrate surface, a first substrate edge that extends from the first substrate surface to the second substrate surface, and a second substrate edge that extends from the first substrate surface to the second substrate surface and is arranged opposite to the first substrate edge, wherein a first series of holes is arranged along the first substrate edge of the circuit substrate to form a first perforated edge, wherein each hole of the first series of holes extends at least partially from the first substrate surface toward the second substrate surface, wherein a second series of holes is arranged along the second substrate edge of the circuit substrate to form a second perforated edge, wherein each hole of the second series of holes extends at least partially from the first substrate surface toward the second substrate surface; at least one memory die arranged on the first substrate surface; and a package molding disposed on the first substrate surface, wherein the package molding encapsulates the at least one memory die and the first substrate surface, and wherein the package molding fills the first series of holes and the second series of holes.

Aspect 19: The memory device of Aspect 18, wherein the at least one memory die includes a first die edge arranged laterally from the first substrate edge by 100 micrometers or less and a second die edge arranged opposite to the first die edge and arranged laterally from the second substrate edge by 100 micrometers or less.

Aspect 20: The memory device of any of Aspects 18-19, wherein each hole of the first series of holes and each hole of the second series of holes are half-holes.

Aspect 21: The memory device of any of Aspects 18-20, wherein each hole of the first series of holes and each hole of the second series of holes extends partially from the first substrate surface to the second substrate surface.

Aspect 22: The memory device of any of Aspects 18-21, wherein each hole of the first series of holes and each hole of the second series of holes extends entirely from the first substrate surface to the second substrate surface.

Aspect 23: A semiconductor package, comprising: a circuit substrate comprising a first substrate surface, a second substrate surface arranged opposite to the first substrate surface, a first substrate edge that extends from the first substrate surface to the second substrate surface, a second substrate edge that extends from the first substrate surface to the second substrate surface and is arranged opposite to the first substrate edge, a third substrate edge that extends from the first substrate surface to the second substrate surface, and a fourth substrate edge that extends from the first substrate surface to the second substrate surface and is arranged opposite to the third substrate edge; wherein a first series of holes is arranged along the first substrate edge of the circuit substrate to form a first perforated edge, wherein each hole of the first series of holes extends at least partially from the first substrate surface toward the second substrate surface, wherein a second series of holes is arranged along the second substrate edge of the circuit substrate to form a second perforated edge, wherein each hole of the second series of holes extends at least partially from the first substrate surface toward the second substrate surface wherein a third series of holes is arranged along the third substrate edge of the circuit substrate to form a third perforated edge, wherein each hole of the third series of holes extends at least partially from the first substrate surface toward the second substrate surface, wherein a fourth series of holes is arranged along the fourth substrate edge of the circuit substrate to form a fourth perforated edge, wherein each hole of the fourth series of holes extends at least partially from the first substrate surface toward the second substrate surface; at least one die arranged on the first substrate surface; and a package casing disposed over the first substrate surface, wherein the package casing encapsulates the at least one die and the first substrate surface, and wherein the package casing fills each hole of the first series of holes, the second series of holes, the third series of holes, and the fourth series of holes.

Aspect 24: The semiconductor package of Aspect 23, wherein each hole of the first series of holes, the second series of holes, the third series of holes, and the fourth series of holes has a perimeter defined by a circular segment.

Aspect 25: A method, comprising: attaching at least one die to a circuit substrate, the circuit substrate comprising a first substrate surface on which the at least one die is arranged, a second substrate surface arranged opposite to the first substrate surface, and a series of holes arranged along a first saw path, wherein each hole of the series of holes extends at least partially from the first substrate surface toward the second substrate surface; depositing a casing material on the first substrate surface, including on the first saw path, to encapsulate the at least one die, wherein depositing the casing material includes filling the series of holes with the casing material; and sawing through the casing material and the circuit substrate along the first saw path to form a package edge of a semiconductor package assembly, wherein the casing material deposited in the series of holes forms a portion of the package edge.

Aspect 26: The method of Aspect 25, wherein: sawing through the casing material and the circuit substrate along the first saw path forms a substrate edge of the circuit substrate as part of the package edge, and the casing material is mechanically interlocked with the circuit substrate along the substrate edge.

Aspect 27: The method of Aspect 26, wherein the substrate edge of the semiconductor package assembly includes a remaining portion of each hole of the series of holes, and the remaining portion of each hole of the series of holes has a perimeter defined by a circular segment.

Aspect 28: The method of any of Aspects 25-27, wherein each hole of the series of holes extends partially from the first substrate surface to the second substrate surface.

Aspect 29: The method of Aspect 28, wherein: a bottom of each hole of the series of holes is defined by the circuit substrate, and the casing material is in direct contact with the circuit substrate along the bottom of each hole of the series of holes.

Aspect 30: The method of any of Aspects 25-29, wherein each hole of the series of holes extends entirely from the first substrate surface to the second substrate surface.

Aspect 31: A method, comprising: attaching at least one first die to a first device region of a circuit substrate; attaching at least one second die to a second device region of the circuit substrate, wherein the circuit substrate comprises a first substrate surface on which the at least one first die and the at least one second die are arranged, and a second substrate surface arranged opposite to the first substrate surface, wherein the first device region and the second device region are delineated by a series of holes arranged along a first singulation path, wherein each hole of the series of holes extends at least partially from the first substrate surface toward the second substrate surface; depositing a casing material on the first substrate surface, including depositing the casing material over the at least one first die, the at least one second die, and the first singulation path to encapsulate the at least one first die, the at least one second die, and the first singulation path, wherein depositing the casing material includes filling the series of holes with the casing material; and cutting through the casing material and the circuit substrate along the first singulation path to separate the first device region and the second device region to form a first package edge of a first semiconductor package assembly corresponding to the first device region and form a second package edge of a second semiconductor package assembly corresponding to the second device region, wherein the casing material deposited in the series of holes forms a portion of the first package edge and the second package edge.

Aspect 32: The method of Aspect 31, wherein: cutting through the casing material and the circuit substrate along the first singulation path forms a first substrate edge of the circuit substrate as part of the first package edge and forms a second substrate edge of the circuit substrate as part of the second package edge, the casing material is mechanically interlocked with the circuit substrate of the first semiconductor package assembly along the first substrate edge, and the casing material is mechanically interlocked with the circuit substrate of the second semiconductor package assembly along the second substrate edge.

Aspect 33: The method of Aspect 32, wherein: the first substrate edge of the first semiconductor package assembly includes a first remaining portion of each hole of the series of holes, and the first remaining portion of each hole of the series of holes has a first shape defined by a first circular segment, and the second substrate edge of the second semiconductor package assembly includes a second remaining portion of each hole of the series of holes, and the second remaining portion of each hole of the series of holes has a second shape defined by a second circular segment.

Aspect 34: The method of any of Aspects 31-33, wherein: wherein the series of holes is a first series of holes, wherein the first device region is further delineated by a second series of holes arranged along a second singulation path, wherein each hole of the second series of holes extends at least partially from the first substrate surface toward the second substrate surface, wherein the second device region is further delineated by a third series of holes arranged along a third singulation path, wherein each hole of the third series of holes extends at least partially from the first substrate surface toward the second substrate surface, wherein depositing the casing material on the first substrate surface further comprises depositing the casing material over the second singulation path and the third singulation path to encapsulate the second singulation path and the third singulation path, wherein depositing the casing material on the first substrate surface further comprises filling the second series of holes and the third series of holes with the casing material, wherein the method further comprises: cutting through the casing material and the circuit substrate along the second singulation path to form a third package edge of the first semiconductor package assembly, wherein the casing material deposited in the second series of holes forms a portion of the third package edge; and cutting through the casing material and the circuit substrate along the third singulation path to form a fourth package edge of the second semiconductor package assembly, wherein the casing material deposited in the third series of holes forms a portion of the fourth package edge. cutting through the casing material and the circuit substrate along the second singulation path to form a third package edge of the first semiconductor package assembly, wherein the casing material deposited in the second series of holes forms a portion of the third package edge; and cutting through the casing material and the circuit substrate along the third singulation path to form a fourth package edge of the second semiconductor package assembly, wherein the casing material deposited in the third series of holes forms a portion of the fourth package edge.

Aspect 35: The method of Aspect 34, wherein the first singulation path, the second singulation path, and the third singulation path extend parallel to each other.

Aspect 36: A system configured to perform one or more operations recited in one or more of Aspects 1-35.

Aspect 37: An apparatus comprising means for performing one or more operations recited in one or more of Aspects 1-35.

Aspect 38: A non-transitory computer-readable medium storing a set of instructions, the set of instructions comprising one or more instructions that, when executed by a device, cause the device to perform one or more operations recited in one or more of Aspects 1-35.

Aspect 39: A computer program product comprising instructions or code for executing one or more operations recited in one or more of Aspects 1-35.

The foregoing disclosure provides illustration and description but is not intended to be exhaustive or to limit the implementations to the precise forms disclosed. Modifications and variations may be made in light of the above disclosure or may be acquired from practice of the implementations described herein.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise.

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a circuit substrate comprising a first substrate surface, a second substrate surface arranged opposite to the first substrate surface, a first substrate edge that extends from the first substrate surface to the second substrate surface, and a second substrate edge that extends from the first substrate surface to the second substrate surface and is arranged opposite to the first substrate edge;
a series of holes arranged along the first substrate edge of the circuit substrate, wherein each hole of the series of holes extends at least partially from the first substrate surface toward the second substrate surface;
at least one die arranged on the first substrate surface; and
a package casing disposed over the first substrate surface, wherein the package casing encapsulates the at least one die and the first substrate surface, and wherein the package casing fills each hole of the series of holes.

2. The semiconductor device assembly of claim 1, wherein the package casing is mechanically interlocked with the first substrate edge.

3. The semiconductor device assembly of claim 1, wherein the first substrate edge is a perforated edge formed with the series of holes.

4. The semiconductor device assembly of claim 1, wherein each hole of the series of holes defines a respective concaved segment of the first substrate edge.

5. The semiconductor device assembly of claim 1, wherein each hole of the series of holes has a perimeter having a substantially semicircular shape.

6. The semiconductor device assembly of claim 1, wherein each hole of the series of holes extends partially from the first substrate surface to the second substrate surface.

7. The semiconductor device assembly of claim 6, wherein:
a bottom of each hole of the series of holes is defined by the circuit substrate, and
the package casing is in direct contact with the circuit substrate at the bottom of each hole of the series of holes.

8. The semiconductor device assembly of claim 1, wherein each hole of the series of holes extends entirely from the first substrate surface to the second substrate surface.

9. The semiconductor device assembly of claim 1, wherein:
the circuit substrate comprises a solder mask formed on the first substrate surface to cover the first substrate surface, wherein the first substrate surface is exposed at the first substrate edge, with the solder mask being absent therefrom, and the package casing is in direct contact with the first substrate surface at the first substrate edge.

10. The semiconductor device assembly of claim 9, wherein the first substrate surface is a prepreg layer or a core layer.

11. The semiconductor device assembly of claim 1, wherein:
the series of holes is a first series of holes, and
the semiconductor device assembly further comprises:
a second series of holes arranged along the second substrate edge of the circuit substrate, wherein each hole of the second series of holes extends at least partially from the first substrate surface toward the second substrate surface,
wherein the package casing fills the second series of holes.

12. The semiconductor device assembly of claim 11, wherein the package casing is mechanically interlocked with the first substrate edge and the second substrate edge.

13. The semiconductor device assembly of claim 11, wherein the first substrate edge is a first perforated edge formed with the first series of holes and the second substrate edge is a second perforated edge formed with the second series of holes.

14. The semiconductor device assembly of claim 11, wherein each hole of the first series of holes and each hole of the second series of holes has a perimeter bounded by an arc and a chord of a circle.

15. The semiconductor device assembly of claim 1, wherein the at least one die includes a plurality of dies arranged in a stacked configuration, wherein the at least one die includes a die edge arranged laterally from the first substrate edge by 100 micrometers or less.

16. A memory device, comprising:
a circuit substrate comprising a first substrate surface, a second substrate surface arranged opposite to the first substrate surface, a first substrate edge that extends from the first substrate surface to the second substrate surface, and a second substrate edge that extends from the first substrate surface to the second substrate surface and is arranged opposite to the first substrate edge,
wherein a first series of holes is arranged along the first substrate edge of the circuit substrate to form a first perforated edge, wherein each hole of the first series of holes extends at least partially from the first substrate surface toward the second substrate surface,
wherein a second series of holes is arranged along the second substrate edge of the circuit substrate to form a second perforated edge, wherein each hole of the second series of holes extends at least partially from the first substrate surface toward the second substrate surface;
at least one memory die arranged on the first substrate surface; and
a package molding disposed on the first substrate surface, wherein the package molding encapsulates the at least one memory die and the first substrate surface, and wherein the package molding fills the first series of holes and the second series of holes.

17. The memory device of claim 16, wherein the at least one memory die includes a first die edge arranged laterally from the first substrate edge by 100 micrometers or less and a second die edge arranged opposite to the first die edge and arranged laterally from the second substrate edge by 100 micrometers or less.

18. A method, comprising:
attaching at least one die to a circuit substrate, the circuit substrate comprising a first substrate surface on which the at least one die is arranged, a second substrate surface arranged opposite to the first substrate surface, and a series of holes arranged along a first saw path, wherein each hole of the series of holes extends at least partially from the first substrate surface toward the second substrate surface;
depositing a casing material on the first substrate surface, including on the first saw path, to encapsulate the at least one die, wherein depositing the casing material includes filling the series of holes with the casing material; and
sawing through the casing material and the circuit substrate along the first saw path to form a package edge of a semiconductor package assembly,
wherein the casing material deposited in the series of holes forms a portion of the package edge.

19. The method of claim 18, wherein:
sawing through the casing material and the circuit substrate along the first saw path forms a substrate edge of the circuit substrate as part of the package edge, and
the casing material is mechanically interlocked with the circuit substrate along the substrate edge.

20. The method of claim 19, wherein the substrate edge of the semiconductor package assembly includes a remaining portion of each hole of the series of holes, and the remaining portion of each hole of the series of holes has a perimeter defined by a circular segment.
